(19) United States
(12) Patent Application Publication
(10) Pub. No.: US 2024/0397834 A1
(43) Pub. Date: Nov. 28, 2024

(54) (Nb1-xTix)N SUPERCONDUCTING NANOWIRE SINGLE-PHOTON DETECTORS WITH INTEGRATED TRANSITION-METAL NITRIDE REFLECTORS

(71) Applicant: HERMES-EPITEK CORPORATION, Taipei (TW)

(72) Inventors: Shang-Jr Gwo, New Taipei City (TW); Chang-Wei Cheng, Miaoli County (TW)

(21) Appl. No.: 18/789,404

(22) Filed: Jul. 30, 2024

Related U.S. Application Data
(63) Continuation-in-part of application No. 17/966,502, filed on Oct. 14, 2022, now Pat. No. 12,078,535.

(51) Int. Cl. H10N 60/84; G01J 1/44; H10N 60/83; H10N 60/85

(52) U.S. Cl. CPC H10N 60/84; G01J 1/44; H10N 60/83; H10N 60/85; G01J 2001/442

(57) ABSTRACT

The invention provides a single-photon detector structure that includes a superconducting nanowire made from a single-crystalline and uniform superconducting film. A transparent dielectric layer and an integrated transition-metal nitride reflector are combined to collect an incident light to the superconducting nanowire. A surface-plasmon wavelength-selective surface may be further provided above the superconducting nanowire to resonantly transmits the incident light within a selective optical passband, making the single-photon detector operable in a broad wavelength range. In addition, a large area of superconducting film with a high level of film uniformity is grown to achieve the up scaling of single-photon detectors into a single-photon detector array.

### CROSS-REFERENCE TO RELATED APPLICATIONS

This application is a continuation in part application of application Ser. No. 17/966,502, filed Oct. 14, 2022 and entitled “SINGLE-PHOTON DETECTOR AND ARRAY AND FABRICATING METHOD THEREOF.” The entire contents of the foregoing application are incorporated herein by reference.

### BACKGROUND OF THE INVENTION

### 1. Field of the Invention

The invention relates to the field of light detection, and more precisely the invention relates to a single-photon detector and a single-photon detector array operable in a broad spectral range. The invention further relates to the method for manufacturing the single-photon detector and the single-photon detector array

### 2. Description of Related Art

The superconducting nanowire single-photon detectors (SNSPDs) are optical detectors to detect the smallest amounts of light. SNSPDs play an increasing role in applications like quantum optics, photonic quantum computing, quantum key distribution, optical communications, and light detection and ranging (LIDAR). In terms of detector performance, SNSPDs stand out due to high detection efficiency, picosecond-order time resolution, short recovery time, and low dark count rate.

SNSPDs detect photons based on the following principle. The nanowire is cooled below its superconducting critical temperature and biased with a direct current slightly below the superconducting critical current of the nanowire. Once a single photon is absorbed in the meandering nanowire, the superconductivity of the nanowire is locally broken. The localized non-superconducting area or hot spot with finite electrical resistance produces a measurable voltage pulse to be detected. After the hot spot relaxation, superconductivity recovers in the nanowire within a short period of time and the SNSPD is ready to detect the next photon.

In single-photon detectors, an optical fiber is generally employed to guide the light to be detected to the detector element, e.g., the superconducting nanowire. The coupling loss occurs between the end of optical fiber and the detector element, leading to a reduction in the efficiency of the detectors. The absorption in the superconducting nanowire can be boosted by varied methods. U.S. Pat. No. 9,500,519 B2 discloses an SNSPD integrated into a chip. A planar waveguide is located on a substrate, and the nanowire is placed on the waveguide. U.S. Pat. No. 9,726,536 B2 discloses an SNSPD that is manufactured directly on the tip of an optical fiber. This configuration boosts the absorption by the back and forth reflection of the optical signal in the optical cavity. U.S. Pub. 2021/0381884 A1 discloses a single-photon detector comprising an optical fiber and at least one nanowire, wherein the optical fiber comprises a core and a cladding, a first area of the optical fiber is an entrance area for the optical signal and a second area of the optical fiber is a detector area, and in the detector area the nanowire extends essentially along the optical axis of the optical fiber.

So far, SNSPDs have been primarily used in research and development and have the disadvantage of the spectral range in which the single-photon detector operates efficiently being small. In addition, existing SNSPDs are difficult to manufacture. In addition, for the detection of longer wavelength photons, the detection efficiency of standard SNSPDs decreases significantly¹. Furthermore, large SNSPD arrays are beneficial for quantum imaging, time-and spatially resolved imaging, optical spectrometer, or LIDAR applications. However, these applications generally require larger arrays than are currently available, both in terms of number of elements and active area. Current device technology is generally limited to single device and needs to be improved to achieve large-scale SNSPDs in real-world applications.

References: [1] A. Korneev, V. Matvienko, O. Minaeva, I. Milostnaya, I. Rubtsova, G. Chulkova, K. Smimov, V. Voronov, G. Gol'tsman, W. Słysz, A. Pearlman, A. Verevkin, and R. Sobolewski, “Quantum efficiency and noise equivalent power of nanostructured, NbN, single-photon detectors in the wavelength range from visible to infrared.” IEEE Transactions on Applied Superconductivity, vol. 15, pp. 571-574 (2005); [2] C.-W. Cheng, Y.-J. Liao, C.-Y. Liu, B.-H. Wu, S. S. Raja, C.-Y. Wang, X. Li, C.-K. Shih, L.-J. Chen, and S. Gwo, “Epitaxial aluminum-on-sapphire films as a plasmonic material platform for ultraviolet and full visible spectral regions,” ACS Photonics, vol. 5, pp. 2624-2630 (2018); [3] W.-P. Guo, R. Mishra, C.-W. Cheng, B.-H. Wu, L.-J. Chen, M.-T. Lin, and S. Gwo, “Titanium nitride epitaxial films as a plasmonic material platform: alternative to gold.” ACS Photonics, vol. 6, pp. 1848-1854 (2019); [4] R. Cheng, S. Wang, and H. X. Tang. “Superconducting nanowire single-photon detectors fabricated from atomic-layer-deposited NbN,” Appl. Phys. Lett., vol. 115, 241101 (2019).

### SUMMARY OF THE INVENTION

In one aspect, a single-photon detector is provided for detecting an incident light and includes a substrate, an integrated transition-metal nitride reflector disposed on the substrate, a transparent dielectric layer disposed on the integrated transition-metal nitride reflector, and at least one superconducting nanowire, preferably single-crystalline, disposed on the reflector or the substrate, wherein the incident light is irradiated on the at least one superconducting nanowire and/or is reflected to the at least one superconducting nanowire by the underlying integrated transition-metal nitride reflector.

In another aspect, in addition to the above architecture, the single-photon detector further includes a dielectric layer covering the at least one superconducting nanowire and a surface-plasmon wavelength-selective surface comprising a nanostructure array on the dielectric layer, wherein the nanostructure array is configured to enable surface plasmon resonances stimulated by the incident light at one or more wavelengths, the surface-plasmon wavelength-selective surface resonantly transmits the incident light within an optical passband, and the transmitted light is irradiated on the at least one superconducting nanowire and/or is reflected to the at least one superconducting nanowire by the integrated transition-metal nitride reflector.

In another aspect, a single-photon detector array is provided for detecting an incident light and includes a substrate divided into a plurality of pixels, wherein each pixel includes architecture similar to the single-photon detectors described above, and wherein the center wavelength of the transmitted passband of each pixel may differ from that of adjacent pixels.

In another aspect, a method is provided for manufacturing the described single photon detectors and the single photon detector array. The method comprises the steps of: providing a substrate; forming an integrated transition-metal nitride reflector disposed on the substrate; forming a transparent dielectric layer disposed on the integrated transition-metal nitride reflector; forming a superconducting layer on the transparent dielectric layer under ultrahigh vacuum (UHV) conditions; and patterning the superconducting layer to form at least one superconducting nanowire. The method may further comprise: forming a dielectric layer to cover the at least one superconducting nanowire; forming a conductive layer on the dielectric layer; and patterning the conductive layer to form a surface-plasmon wavelength-selective surface comprising a nanostructure array configured to enable surface plasmon resonances stimulated by an incident light at one or more wavelengths. In the best embodiment, each layer making up the single-photon detector is lattice matched to the layer below it. In the best embodiment, both the integrated transition-metal nitride reflector and the transparent dielectric layer are also grown under UHV conditions.

By improvements in fabrication and material growth technique, a high-efficiency single-photon detector is made from a single-crystalline and uniform superconducting film with a superconducting critical temperature reachable by available cryostats. In addition, a large area of superconducting film with high level of uniformity can be grown to realize the up scaling of the single-photon detectors. A large-scale superconducting single-photon detector array provides unmatched performances for detection and imaging over a broad spectral bandwidth.

### BRIEF DESCRIPTION OF THE DRAWINGS

FIG. 1 is a schematic cross-sectional view showing a single-photon detector in accordance with an embodiment of the earlier invention (Ser. No. 17/966,502).

FIG. 2 is a schematic cross-sectional view showing a single-photon detector in accordance with another embodiment of the earlier invention (Ser. No. 17/966,502).

FIG. 3 is a schematic top view showing superconducting nanowires in accordance with some embodiments of the earlier invention (Ser. No. 17/966,502).

FIG. 4 is a schematic top view showing surface-plasmon wavelength-selective surfaces in accordance with some embodiments of the earlier invention (Ser. No. 17/966,502).

FIG. 5 is a schematic cross-sectional view showing a single-photon detector array in accordance with an embodiment of the earlier invention (Ser. No. 17/966,502).

FIG. 6 is a schematic cross-sectional view showing a single-photon detector in accordance with one embodiment of the present invention.

FIG. 7 is a schematic cross-sectional view showing a single-photon detector in accordance with another embodiment of the present invention.

FIG. 8 shows lattice structures, epitaxial relationships, and X-ray diffraction patterns of a NbN ultrathin film grown on a lattice-matched substrate and/or overlayer by using molecule-beam epitaxy (MBE) under UHV conditions, according to some examples of this invention.

FIG. 9 shows atomic concentration depth profiles of a MBE-grown TiN epitaxial film, in comparison to sputtered TiN and NbN films from the prior art.

FIG. 10 shows superconducting properties of MBE-grown NbN and TiN epitaxial films from this invention

FIG. 11 shows X-ray diffraction pattern and atomic concentration depth profile of a NbN epitaxial film prepared from another example of this invention.

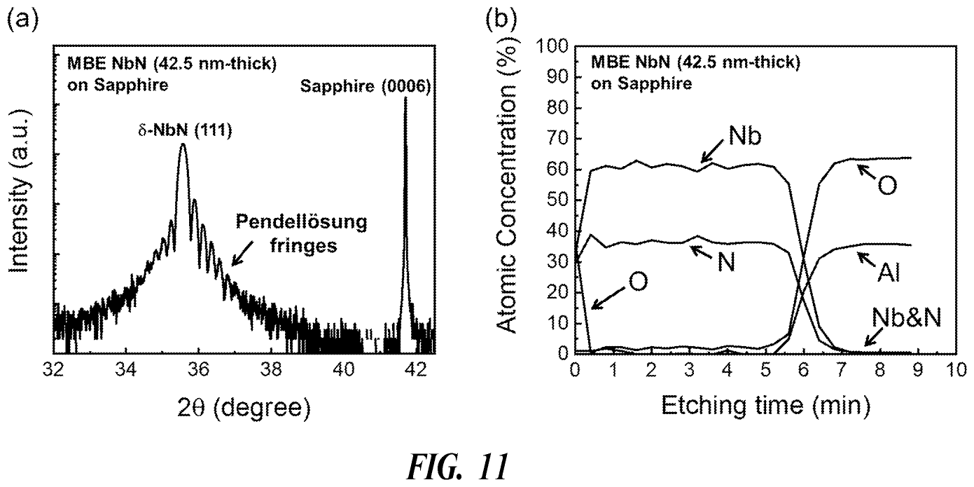

FIG. 12 shows optical properties of a MBE-grown TIN epitaxial film from an example of this invention.

### DETAILED DESCRIPTION OF THE PREFERRED EMBODIMENT

Reference will now be made in detail to those specific embodiments of the invention. Examples of these embodiments are illustrated in accompanying drawings. While the invention will be described in conjunction with these specific embodiments, it will be understood that it is not intended to limit the invention to these embodiments. On the contrary, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In other instances, well-known process operations and components are not described in detail in order not to unnecessarily obscure the present invention. While drawings are illustrated in detail, it is appreciated that the quantity of the disclosed components may be greater or less than that disclosed, except where expressly restricting the amount of the components. Wherever possible, the same or similar reference numbers are used in drawings and the description to refer to the same or like parts.

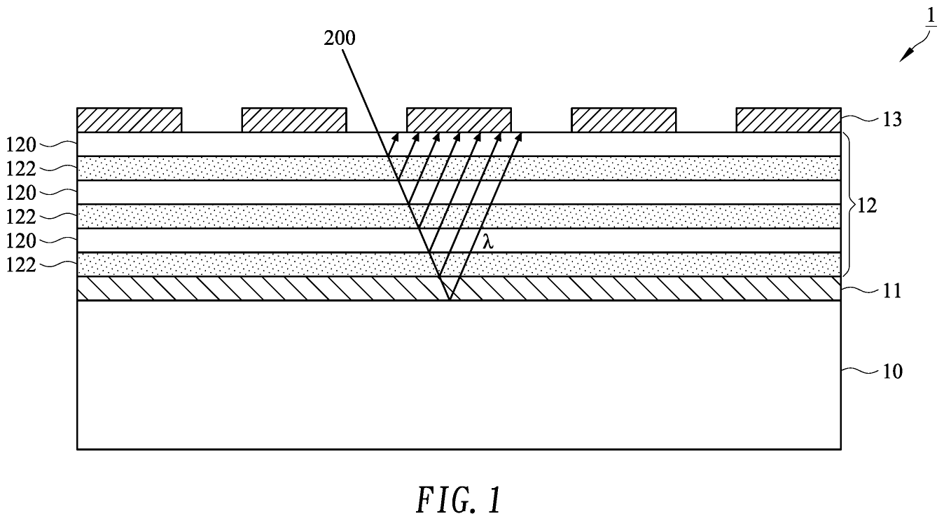

FIG. 1 is a schematic diagram showing a single-photon detector 1 in accordance with an embodiment of the invention. Referring to FIG. 1, the single-photon detector 1 is used for detecting an incident light 200 and generally includes a substrate 10, a reflector 12 disposed on the substrate 10, and at least one superconducting nanowire 13 disposed on the reflector 12. In addition, an optional buffer layer 11 may be interposed between the reflector 12 and the substrate 10. The incident light 200 is irradiated on the at least one superconducting nanowire 13 and/or is reflected to the at least one superconducting nanowire 13 by the reflector 12.

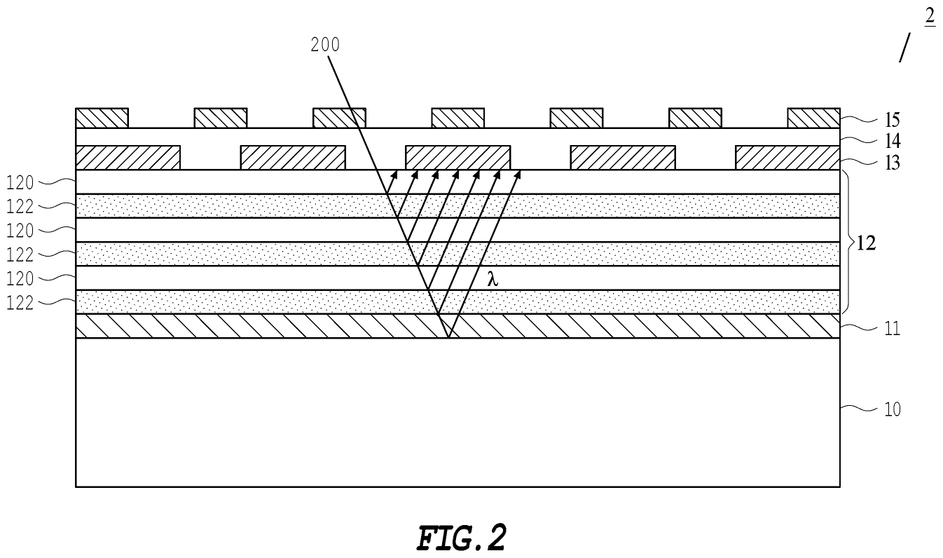

FIG. 2 is a schematic diagram showing a single-photon detector 2 in accordance with another embodiment of the invention. The single-photon detector 2 is similar to the single-photon detector 1 described in FIG. 1, except as described below. In addition to the architecture presented in FIG. 1, the single-photon detector 2 further includes: a dielectric layer 14 covering the at least one superconducting nanowire 13, and a surface-plasmon wavelength-selective surface 15 disposed on the dielectric layer 14. The surface-plasmon wavelength-selective surface 15 includes a nanostructure array configured to enable surface plasmon resonances (SPR) stimulated by the incident light 200 at one or more wavelengths. The surface-plasmon wavelength-selective surface IS resonantly transmits the incident light 200 within an optical passband, and the transmitted light is irradiated on the at least one superconducting nanowire 13 and/or is reflected to the at least one superconducting nanowire 13 by the reflector 12.

Referring to FIGS. 1 and 2, the reflector 12 is preferably multilayered and is deposited or epitaxially grown on the substrate 10. The substrate 10 is preferably made of silicon carbide, including single-crystalline silicon carbide with the hexagonal crystal structure (4H-SiC and 6H-SiC), or the cubic crystal structure (3C-SIC). The substrate 10 may also be made of any other lattice-matched materials, such as silicon, sapphire (Al₂O₃), other semiconductors, or other dielectric materials. In case of the substrate 10 is not made of, e.g., silicon carbide, a buffer layer 11 may be firstly formed on the top surface of the substrate 10, and then the reflector 12 is formed on the buffer layer 11. The reflector 12 can be a distributed Bragg reflector (DBR) that includes multiple pairs of layers formed of high refractive index and low refractive index materials. The reflector 12 can be formed by alternating deposition of the high and low index materials using a chemical vapor deposition or a physical vapor deposition process. Preferably, each layer of the reflector 12 is single-crystalline. In the exemplary embodiment, nitrogen-plasma-assisted molecular-beam epitaxy (MBE, a precise form of PVD) is adopted to grow alternating single-crystalline high and low index materials on the substrate 10.

The thicknesses and materials (and thus indices of refraction) in the multilayered reflector 12 are selected to increase reflection (reflectivity >99%) in a selected wavelength or wavelength band. For example, the controlled multilayered reflector 12 may be optimized for reflection of light of the center wavelength λ of the optical passband transmitted from the surface-plasmon wavelength-selective surface 15. In the example shown in FIG. 1, the multilayered reflector 12 may be optimized for reflection of the incident light 200 with the center wavelength λ.

In some embodiments, the controlled multilayered reflector 12 includes pairs of high/low refractive index materials, and each pair includes a high-refractive-index layer 120 and a low-refractive-index layer 122. Preferably, both the alternating high-refractive-index layers 120 and the low-refractive-index layers 122 are made of group-III nitride materials. In some embodiments, both the alternating high-refractive-index layers 120 and the low-refractive-index layers 122 are made of dielectrics or oxides. In one embodiment, the alternating high-refractive-index layers 120 and the low-refractive-index layers 122 comprise GaN/AlN alternating layers. In one embodiment, the alternating high-refractive-index layers 120 and the low-refractive-index layers 122 comprise TiO₂/SiO₂ alternating layers. The index difference between the high-refractive-index layers 120 and the low-refractive-index layers 122 is large, and a few pairs of layers of λ/4 optical thickness is sufficient to give very high reflectivity (>99%) as a broadband reflector. In some embodiments, the reference number 120 refers to the low-refractive-index layers, and the reference number 122 refers to the high-refractive-index layers. In some embodiments, the reference number 120 refers to the high-refractive-index layers, and the reference number 122 refers to the low-refractive-index layers. Other materials as known in the art could be used as well for the multilayered broadband reflector 12.

Referring to FIG. 2, the surface-plasmon wavelength-selective surface 15 having the subwavelength nanostructure array is configured to enable surface plasmon resonance (SPR) stimulated by the incident light 200 at one or more wavelengths. In the plasmonic resonant bands, the incident light is resonantly scattered by the subwavelength nanostructure array. The surface-plasmon wavelength-selective surface 15 resonantly transmits the incident light within a certain range of wavelengths Δλ (optical passband) with a center wavelength λ, which is precisely determined by the geometry and size (e.g., thickness, width, depth, diameter) of the subwavelength nanostructure (localized surface plasmon resonance, LSPR), as well as the pitch or periodicity of the subwavelength nanostructure array (collective surface plasmon resonance, CSPR).

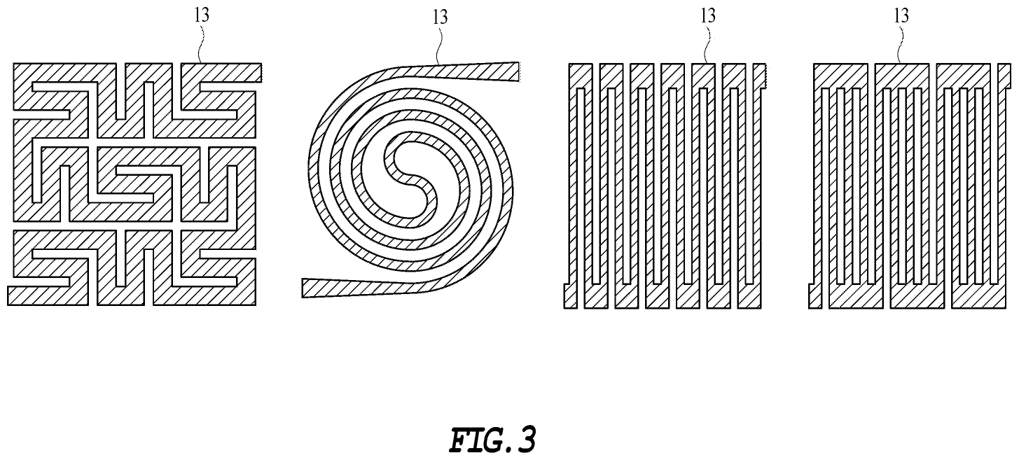

FIG. 3 shows different configurations of superconducting nanowire 13 from directly above in accordance with some embodiment of the invention. The superconducting nanowire 13 can be connected with large-area conductive electrodes (not shown). As illustrated in FIG. 3, the superconducting nanowire 13 can be arranged in, but not limited to, a Peano, spiral, meandering, or parallel pattern, e.g., backward and forward parallel nanostrips on the reflector 12 or the optional buffer layer 11. In some embodiments, multiple superconducting nanowires 13 are connected in parallel between two parallel electrodes. In some embodiments, the superconducting nanowire 13 has an essentially rectangular cross section. In some embodiments, the thickness of the superconducting nanowire 13 is typically less than 15 nm, and the width of the superconducting nanowire 13 is between 10 nm and 150 nm.

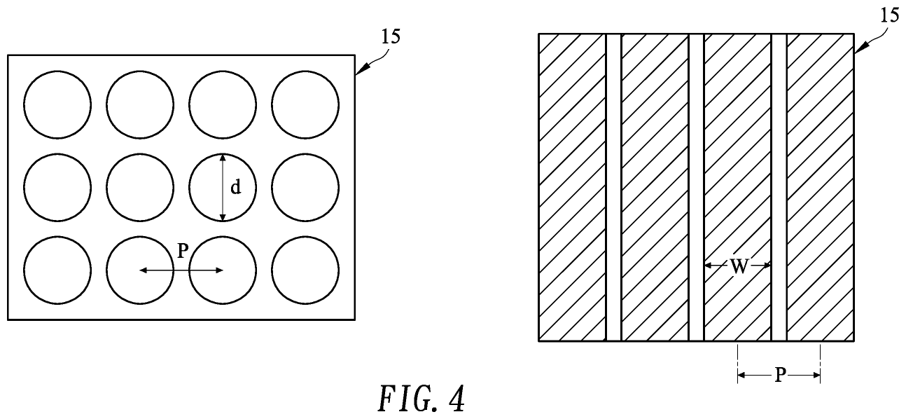

FIG. 4 is a schematic top view showing two examples of surface-plasmon wavelength-selective surface 15 in accordance with an embodiment of the invention. In one exemplary embodiment, the surface-plasmon wavelength-selective surface 1S includes a nanohole array, and the stimulated one or more resonance wavelengths can be determined by, e.g., the diameter (d) of the nanohole and/or the periodicity (p) of the nanohole array. In another exemplary embodiment, the surface-plasmon wavelength-selective surface 15 includes a nanostrip array, and the stimulated one or more resonance wavelengths can be determined by, e.g., the width (w) of the nanostrip and/or the periodicity (p) of the nanostrip array.

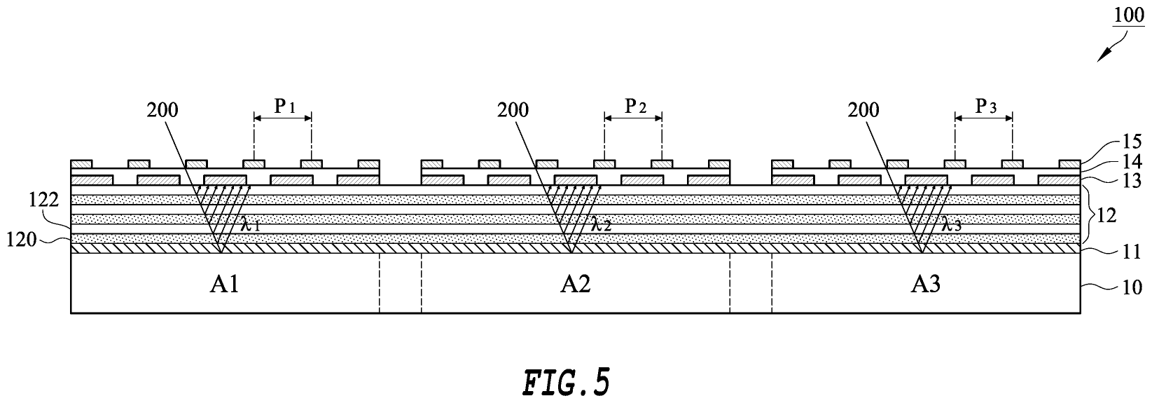

FIG. 5 is a schematic diagram showing a single-photon detector array 100 in accordance with an embodiment of the invention. The single-photon detector array 100 includes single-photon detectors, which are similar to the devices described above with respect to FIG. 2, except as described below. Referring to FIG. 5, the single-photon detector array 100 includes a substrate 10 that is divided into a plurality of areas or pixels, e.g., A1, A2, and A3. In the exemplary embodiment, a multilayered reflector 12 disposed on the substrate 10 or the buffer layer 11 is used as a common reflector for the plurality of pixels. However, each pixel may include an individual reflector 12 in another embodiment. In addition, each pixel includes at least one superconducting nanowire 13 disposed on the reflector 12. a dielectric layer 14 covering the at least one superconducting nanowire 13, and a surface-plasmon wavelength-selective surface 15 having a nanostructure array on the dielectric layer 14. The nanostructure array is configured to enable surface plasmon resonance stimulated by the incident light 2 at one or more wavelengths. Within each pixel, the surface-plasmon wavelength-selective surface 15 resonantly transmits the incident light 2 within an optical passband, and the transmitted light is irradiated on the at least one superconducting nanowire 13 and/or is reflected to the at least one superconducting nanowire 13 by the reflector 12.

Referring to FIG. 5, in some embodiments, the optical passband of the surface-plasmon wavelength-selective surface 15 of each pixel differs from that of an adjacent pixel. For example, the surface plasmonic wavelength selective surface 15 of pixels A1, A2, and A3 has optical passbands Δλ1, Δλ2, and Δλ3, with a center wavelength λ1, λ2, and λ3, respectively. In the exemplary embodiment, Δλ1, Δλ2, and Δλ3 (and hence λ1, λ2, and λ3) are different one another. In the exemplary embodiment, the transmitted center wavelength of the passband of the surface-plasmon wavelength-selective surface 15 of each pixel differs from that of an adjacent pixel. This can be done by that, for example, the nanostructure array of the surface-plasmon wavelength-selective surface 15 of each pixel has an individual periodicity that is different from the adjacent pixels. For example, the periodicities P1, P2, and P3 are different one another in the exemplary embodiment.

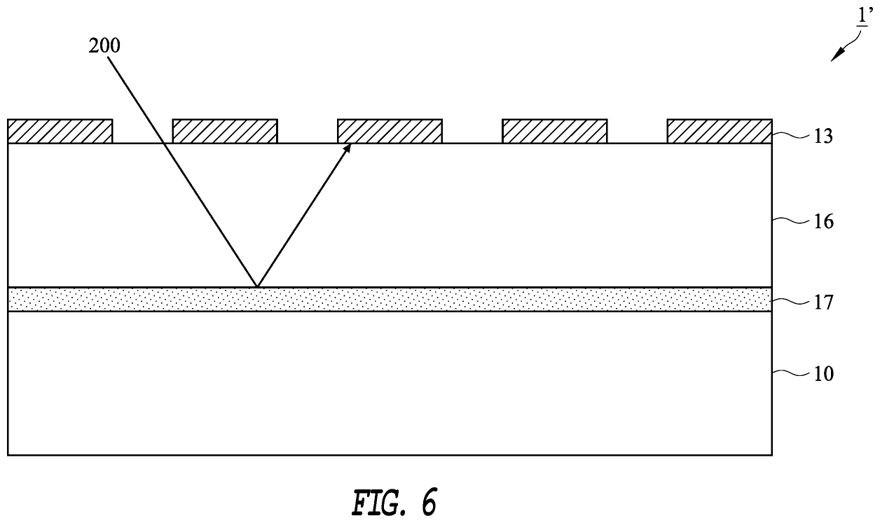

FIG. 6 is a schematic cross-sectional view showing a single-photon detector 1′ in accordance with one embodiment of the present invention. The single-photon detector 1′ is similar to the single-photon detector 1 described in FIG. 1, except as described below. The previous DBR reflector 12 shown in FIGS. 1, 2, and 5 is replaced with a transparent dielectric layer 16 and an integrated transition-metal nitride reflector 17. In some embodiments, the transparent dielectric layer 16 is preferred to have a λ/4 layer thickness (quarter-wave optical thickness) with respect to the wavelength of the incident light. Typically, a group-III nitride compound, such as AlN or AlGaN, can be used for the transparent dielectric layer 16. The transparent dielectric layer 16 is epitaxially grown on the integrated transition-metal nitride reflector 17, which is a layer of transition-metal nitride, e.g., TiN, ZrN, HfN, VN, NbN, TaN, or their alloys, such as (Nb₁₋ₓTiₓ)N and (TI₁₋ₓAlₓ)N, and is epitaxially grown on the lattice-matched substrate 10. Preferably, crystal lattices between the transparent dielectric layer and the integrated transition-metal nitride reflector are matched for epitaxial growth. In a preferred embodiment, the integrated transition-metal nitride reflector 17 is made of TiN due to its excellent optical properties. The substrate 10 can be optically transparent or opaque and preferably made of, e.g., sapphire, silicon carbide, or silicon. The at least one single-crystalline superconducting nanowire 13 is epitaxially grown on the lattice-matched transparent dielectric layer 16 and preferably made of (Nb₁₋ₓTiₓ)N, where 0≤x≤1. Preferably, crystal lattices between the at least one single-crystalline superconducting nanowire 13 and the transparent dielectric layer 16 are matched for epitaxial growth. Preferably, crystal lattices between the integrated transition-metal nitride reflector 17 and the substrate 10 are matched for epitaxial growth. Alternatively, an optional lattice-matched overlayer or buffer layer 11 (FIG. 1) may be interposed between the substrate 10 and the integrated transition-metal nitride reflector 17, and crystal lattices between the integrated transition-metal nitride reflector 17 and the buffer layer 11 are matched for epitaxial growth.

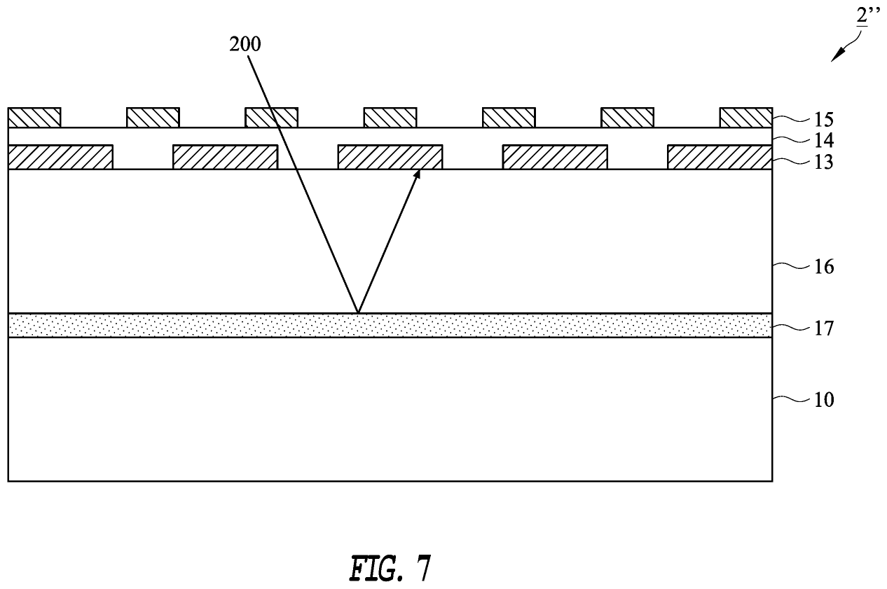

FIG. 7 is a schematic cross-sectional view showing a single-photon detector 2″ in accordance with another embodiment of the present invention. The single-photon detector 2″ is similar to the single-photon detector 1′ described in FIG. 6, except as described below. In addition to the architecture presented in FIG. 6, the single-photon detector 2″ further includes: a dielectric layer 14 covering the at least one superconducting nanowire 13, and a surface-plasmon wavelength-selective surface 15 disposed on the dielectric layer 14. The surface-plasmon wavelength-selective surface 15 includes a nanostructure array configured to enable surface plasmon resonances stimulated by the incident light 200 at one or more wavelengths. The surface-plasmon wavelength-selective surface 15 resonantly transmits the incident light 200 within an optical passband, and the transmitted light is irradiated on the at least one superconducting nanowire 13 and/or is reflected to the at least one superconducting nanowire 13 by the integrated transition-metal nitride reflector 17. In addition, the single-photon detector array 100 shown in FIG. 5 may include single-photon detectors 2″ described above with respect to FIG. 7. By replacing the previous DBR reflector 12 with a transparent dielectric layer 16 and an integrated transition-metal nitride reflector 17, a single-photon detector array can also be made.

The single-photon detector l′ and the single-photon detector 2″ shown in FIGS. 6 and 7 can be fabricated by a method similar to that described in FIGS. 1 and 2 and the earlier invention (Ser. No. 17/966,502). Preferably, a superconducting layer is epitaxially grown on lattice-matched transparent dielectric layer 16 under UHV conditions by using MBE. And then the superconducting layer is patterned to form the at least one superconducting nanowire 13. In addition, the transparent dielectric layer 16 and the integrated transition-metal nitride reflector 17 are also preferably grown by MBE under UHV conditions, and hence both are single-crystalline.

So far, two main classes of superconducting materials have been utilized to fabricate high-efficiency SNSPDₛ⁴: (1) poly-crystalline nitride superconductors such as NbN and NbTiN; (2) amorphous alloy superconductors, such as WSi, MoSi and MoGe. By contrast, material for forming the superconducting layer and thus the at least one superconducting nanowire 13 made from the layer can be selected from the group consisting of epitaxially grown NbN, TiN, Nb₁₋ₓTiₓN, TaN, Nb₁₋ₓTaₓN, and MgB₂ on lattice-matched substrates. In the exemplary embodiments, the at least one superconducting nanowire 13 is made of NbN, TiN, or Nb₁₋ₓTiₓN. X-ray diffraction patterns reveal that the as-grown NbN, TiN, and Nb₁₋ₓTiₓN films on c-plane sapphire substrate or AlN buffer layer are single-crystalline with the (111) orientation, and the as-grown MgB₂ film is single-crystalline with a hexagonal crystal structure. Here, epitaxial growth refers to crystal growth in a state of maintaining continuity of lattice from the substrate. In the case of high-quality and homogenous superconducting layer (e.g., a NbN epitaxial film), one can have a uniform critical temperature (T_{c} in Kelvin) of up to about 16 K. The larger difference between the operating temperature and the critical temperature provides superior detection efficiency, lower dark count, and faster temporal response. Furthermore, the single-photon detectors made from the epitaxially grown superconducting layer can lead to high device yield approaching unity due to the exceptional film homogeneity.

To achieve the best performance, the single-photon detectors of this invention, and array thereof, are fabricated by a superconducting layer with large-area uniformity in thickness and sharp superconducting transition window. As a result, the one or more superconducting nanowires 13, formed by patterning the superconducting layer, have uniform critical current density and ultrafast detector response time across the superconducting nanowire. Especially, these advantages—large-area uniformity, high-purity, and sharp superconducting transition window—can be achieved by epitaxial growth of the superconducting layer on a lattice-matched substrate and/or an overlayer under UHV conditions.

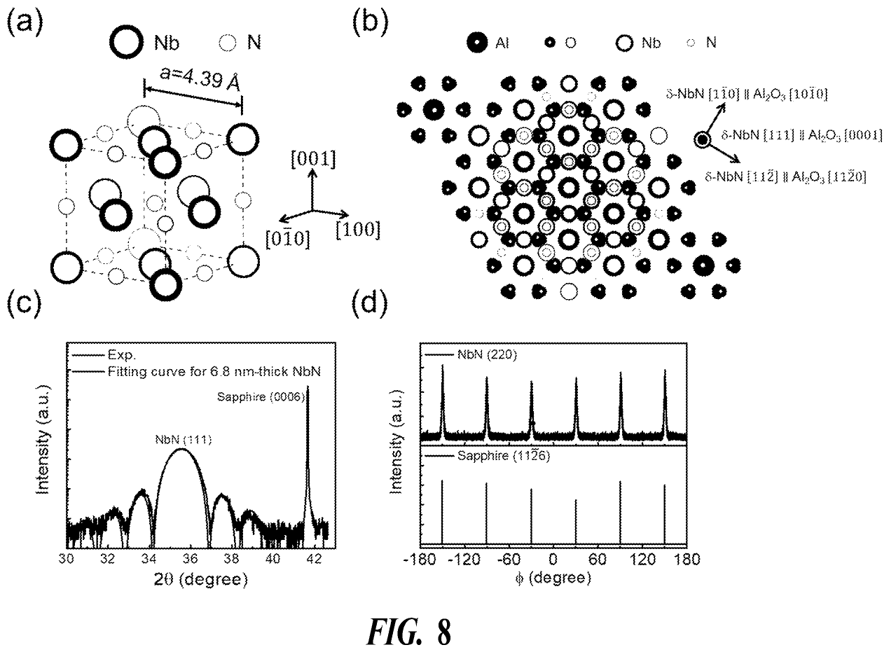

FIG. 8 shows that an NbN ultrathin epitaxial film with thickness less than 10 nm is grown on lattice-matched substrates and/or overlayers, e.g., sapphire (Al₂O₃) substrate or aluminum nitride (AlN) overlayer on sapphire by using MBE under UHV conditions, where panel (a) shows unit cell and lattice parameter of the grown δ-phase NbN crystal structure (δ-NbN, a rock-salt crystal structure). Panel (b) schematically illustrates that epitaxial NbN films with the rock-salt structure can be grown on c-plane (normal direction: [0001]) sapphire substrates with well-defined epitaxial relationships. Panel (c) shows X-ray diffraction pattern (2θ-scan) for a MBE-grown 6.8 nm-thick NbN film, indicating clearly the δ-NbN (111) peak, X-ray inference fringes, and the c-sapphire (0006) peak. Panel (d) shows in-plane X-ray diffraction patterns (ϕ-scan) of δ-NbN and c-sapphire, confirming the epitaxial relationships shown in (b). In addition to well-defined epitaxial relationships with respect to the sapphire (Al₂O₃) substrate, the MBE-grown NbN film reveals the characteristics of large-area single crystalline and ultra-smooth surfaces. The results presented here show that MBE-grown NbN epitaxial films are very suitable for making high-quality superconducting nanowire single-photon detectors.

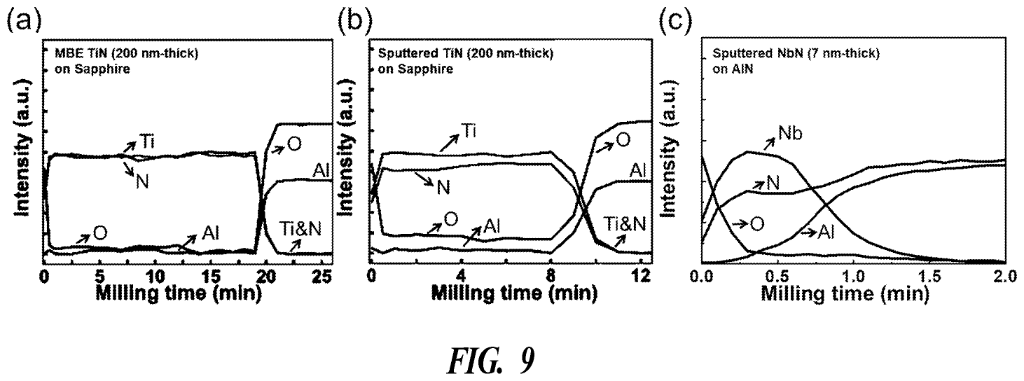

FIG. 9 shows atomic concentration depth profiles of an MBE-grown TIN epitaxial film, in comparison to conventional sputtered TiN and NbN films from the prior art, where, panel (a) shows the atomic depth profile (with respect to the argon-ion milling time) determined by X-ray phtoelectron spectroscopy for the TiN epitaxial film grown by MBE under UHV conditions, and panels (b) and (c) are the atomic depth profiles of sputtered TiN and NbN film grown under conventional high vacuum (HV) conditions. Panel (a) shows that Ti and N concentrations are close to 1:1 in the MBE-grown TiN film, in contrast to the cases of (b) sputtered TiN and (c) sputtered NbN films, which show significant amounts of oxygen (i.e., the sputtered films are actually alloyed films, such as TiOₓN₁₋ₓ or NbOₓN₁₋ₓ). Panels (a,b) are adapted from Ragini Mishra et al., published in J. Phys. Chem. C 125, 13658-13665 (2021) by the inventor of this invention, and panel (c) is unpublished data from the inventor of this invention.

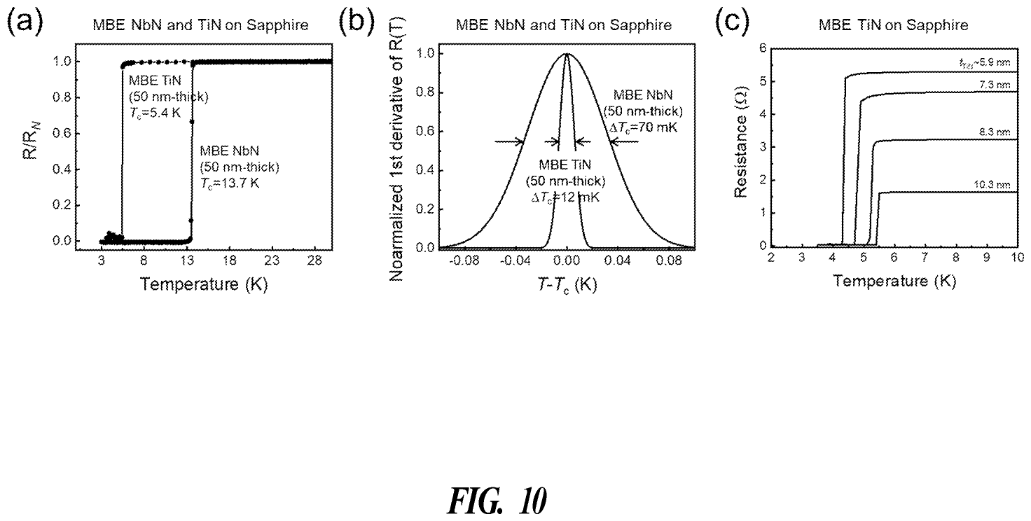

FIG. 10 shows superconducting properties of the MBE-grown NbN and TiN epitaxial films from this invention, where panels (a) and (b) respectively show normalized resistivity (R/R_{N}) as functions of temperature and superconducting transition windows (ΔT_{c}) for MBE-grown NbN and TiN epitaxial films on c-sapphire substrates, in which R_{N} is the normal-state resistivity at 20 K. As shown in panel (b), the MBE-grown NbN and TiN films show very narrow superconducting transition windows (ΔT_{c}), with the values of 70 mK and 12 mK, respectively. Data in (a,b) were measured in the same cryogenic system. The superconducting transition temperatures of NbN and TiN films are depependent on the film thickness (decrease with decreasing film thickness). Panel (c) shows measured resistance (near the transition region) as a function of temperature (K) for ultrathin MBE-grown TiN epitaxial films with thicknesses of 5.9, 7.3. 8.3, and 10.3 nm, respectively. The measured T_{c} transitions are all very sharp and above the liquid helium temperature. These data show that the MBE-grown NbN and TiN epitaxial films, as well as the alloys (i.e., (Nb₁₋ₓTiₓ)N, 0≤x≤1), are very suitable for SNSPD applications.

FIG. Il shows another example of NON epitaxial film with film thickness about 42.5 nm grown by MBE on c-plane sapphire substrate under UHV conditions. Panel (a) shows the X-ray diffraction pattern (2θ-scan) for the MBE-grown NbN film, indicating clearly the δ-NbN (111) peak at 35.5°, X-ray inference Pendellösung fringes, the c-sapphire (0006) peak at 41.7°, and the thickness of the grown NbN film can be estimated to be about 42.5 nm. The Pendellösung Fringes result from X-ray inteference from reflections by abrupt film/substrate interface and ultrasmooth film surface. The XRD patterns show that the MBE-grown NbN film has the characteristics of large-area single crystalline and ultra-smooth surface. Panel (b) shows the atomic concentration depth profile (with respect to the argon-ion milling time) determined by X-ray phtoelectron spectroscopy for the MBE-grown NbN epitaxial film. The chemical compound analysis shows that the MBE-grown NbN epitaxial film contains only niobium and nitrogen and does not contain oxygen, in contrast to panel (c) in FIG. 9. The stoichiometry of the as-grown δ-phase NbN film typically exhibits a Nb vs. N concentration ratio more than one, which is consistent with recent literature studies (e.g., J. G. wright. H. G. Xing, and D. Jena in Phys. Rev. Materials, 7, 074803 (2023).

The results presented here show that the sputtered NbN films grown under conventional high vacuum (HV) conditions contain significant amounts of oxygen. That is, the sputtered films are actually TiO₃N₁₋ₓ or NbOₓN₁₋ₓ films. Therefore, the superconducting layers produced under HV conditions are not single-crystalline. The oxygen-contaminated TiOₓN₁₋ₓ or NbOₓN₁₋ₓ alloyed films typically exhibit broad superconducting transition windows (ΔT_{c}), which will affect the performance of the single-photon detector. By contrast, much narrower superconducting transition windows are observed for the MBE-grown superconducting films used for this invention, and they are also more uniform in terms of supercondting (transition temperature and critical current) and normal-state (resistivy) behavior across the films.

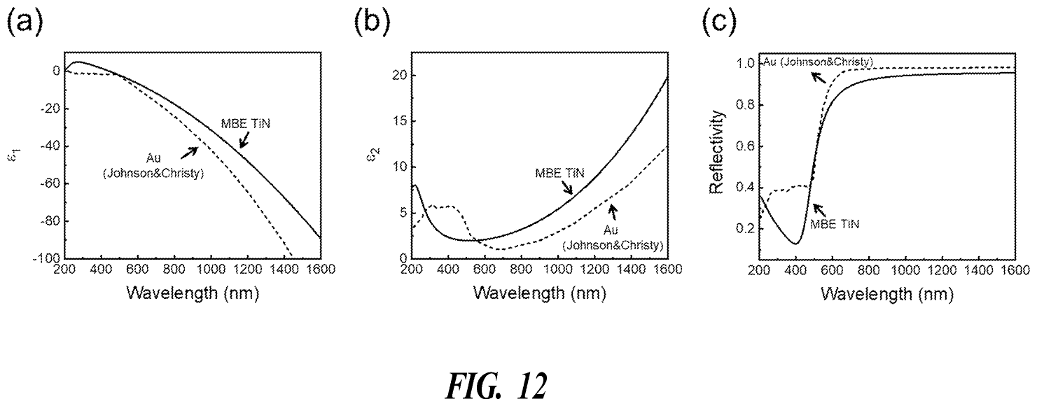

FIG. 12 shows excellent optical properties of the MBE-grown TiN epitaxial film from a previous study by the inventor (Reference, W.-P. Guo et al. in ACS Photonics, vol. 6. pp. 1848-1854(2019)). Panels (a) and (b) show the real and imaginary parts of dielectric function measured by spectroscopic ellipsometry for the MBE-grown TiN epitaxial film, in comparison to that measured for a high-quality gold film (Reference: P. B. Johnson and R. W. Christy in Phys. Rev. B. 6, 4370 (1972)). The reflectivity vs. the incident light wavelength plots shown in panel (c) are deduced from the dielectric functions for both the MBE-grown TiN epitaxial film and the gold film. As shown in panel (c), the MBE-grown TiN film has excellent optical reflectivity (very close to that of gold film, near unity at longer wavelengths) in a broad spectral range from the visible to the infrared region. Therefore, it can be an excellent candidate material as the integrated transition-metal reflector.

The intent accompanying this disclosure is to have each/all embodiments construed in conjunction with the knowledge of one skilled in the art to cover all modifications, variations, combinations, permutations, omissions, substitutions, alternatives, and equivalents of the embodiments, to the extent not mutually exclusive, as may fall within the spirit and scope of the invention.

Conditional language, such as, among others, “can,” “could,” “might,” or “may,” unless specifically stated otherwise, or otherwise understood within the context as used, is generally intended to convey that embodiments include, and in other interpretations do not include, certain features, elements and/or steps. Thus, such conditional language is not generally intended to imply that features, elements and/or steps are in any way required for one or more embodiments, or interpretations thereof, or that one or more embodiments necessarily include logic for deciding. with or without user input or prompting, whether these features, elements and/or steps are included or are to be performed in any particular embodiment.

Although specific embodiments have been illustrated and described, it will be appreciated by those skilled in the art that various modifications may be made without departing from the scope of the present invention, which is intended to be limited solely by the appended claims.

All publications, patents and patent applications mentioned in this specification are herein incorporated in their entirety by reference into the specification. In addition, citation or identification of any reference in this application shall not be construed as an admission that such reference is available as prior art to the present invention. To the extent that section headings are used, they should not be construed as necessarily limiting. In addition, any priority document(s) of this application is/are hereby incorporated herein by reference in its/their entirety.

What is claimed is:

1. A single-photon detector for detecting an incident light, comprising:
a substrate;
an integrated transition-metal nitride reflector disposed on the substrate;
a transparent dielectric layer disposed on the integrated transition-metal nitride reflector;
at least one single-crystalline superconducting nanowire disposed on the transparent dielectric layer;
wherein the at least one single-crystalline superconducting nanowire is made of (Nb₁₋ₓTiₓ)N, 0≤x≤1, and the incident light is irradiated on the at least one superconducting nanowire and/or is reflected to the at least one superconducting nanowire by the integrated transition-metal nitride reflector.

2. The single-photon detector according to claim 1, wherein the transparent dielectric layer is made of a group-III nitride compound.

3. The single-photon detector according to claim 1, wherein the transparent dielectric layer has a λ/4 optical thickness of the wavelength of the incident light.

4. The single-photon detector according to claim 1, wherein the transparent dielectric layer is single-crystalline.

5. The single-photon detector according to claim 1, wherein the integrated transition-metal nitride reflector is single-crystalline.

6. The single-photon detector according to claim 1, further comprising:
a dielectric layer covering the at least one single-crystalline superconducting nanowire; and
a surface-plasmon wavelength-selective surface comprising a nanostructure array on the dielectric layer, the nanostructure array being configured to enable surface plasmon resonances stimulated by the incident light at one or more wavelengths;
wherein the surface-plasmon wavelength-selective surface resonantly transmits the incident light within an optical passband, and the transmitted light is irradiated on the at least one superconducting nanowire and/or is reflected to the at least one single-crystalline superconducting nanowire by the integrated transition-metal nitride reflector.

7. The single-photon detector according to claim 6, wherein a center wavelength of the optical passband is determined by the geometry, size, and the periodicity of nanostructures composing the nanostructure array.

8. The single-photon detector according to claim 7, wherein the center wavelength can be tuned into different optical wavelength covering visible and infrared spectral regions.

9. The single-photon detector according to claim 1, wherein crystal lattices between the at least one single-crystalline superconducting nanowire and the transparent dielectric layer are matched for epitaxial growth.

10. The single-photon detector according to claim 1, wherein crystal lattices between the transparent dielectric layer and the integrated transition-metal nitride reflector are matched for epitaxial growth.

11. The single-photon detector according to claim 1, wherein crystal lattices between the integrated transition-metal nitride reflector and the substrate are matched for epitaxial growth.

12. The single-photon detector according to claim 1, further comprising a buffer layer interposed between the substrate and the integrated transition-metal nitride reflector, and crystal lattices between the buffer layer and the integrated transition-metal nitride reflector are matched for epitaxial growth.

13. The single-photon detector according to claim 6, wherein the nanostructure array is a nanohole array.

14. The single-photon detector according to claim 6, wherein the nanostructure array is a nanostrip array.

15. The single-photon detector according to claim 6, wherein the nanostructure array is made of a plasmonic material selected from the group of metallic materials consisting of aluminum, gold, silver, copper, titanium nitride, and indium-tin-oxide.
